(19) United States
(12) Patent Application Publication
(10) Pub. No.: US 2005/0236030 A1
(43) Pub. Date: Oct. 27, 2005

(54) Photoelectric conversion device and method for manufacturing the same

(75) Inventors: Shin Sugawara, Shiga (JP); Hideki Hakuma, Shiga (JP); Atsuo Hatate, Shiga (JP); Akiko Komoda, Shiga (JP); Hisao Arimune, Shiga (JP)

Correspondence Address: HOGAN & HARTSON L.L.P., 500 S. GRAND AVENUE, SUITE 1900, LOS ANGELES, CA, 90071-2611, US

(73) Assignee: KYOCERA CORPORATION

(21) Appl. No.: 10/998,190

(22) Filed: Nov. 24, 2004

(30) Foreign Application Priority Data
Nov. 27, 2003 (JP) 2003-398181
Nov. 27, 2003 (JP) 2003-398178

(51) Int. Cl. H01L 31/00

(52) U.S. Cl. 136/250

(57) ABSTRACT

A photoelectric conversion device has a structure in which a plurality of crystalline semiconductor particles (3) of one conductivity type each of which has a semiconductor portion (4) of the opposite conductivity type on its surface are joined to a substrate 1 serving as a lower electrode. The substrate (1) and the semiconductor portion (4) are disposed in a state of being separated by a separation portion (6). An insulator (2) is formed between the adjoining crystalline semiconductor particles (3) so as to cover the surface of the substrate (1) and the lower part of the semiconductor portion (4) and so as to expose the upper part of the semiconductor portion (4). An upper electrode (5) is formed so as to cover the insulator (2) and the upper part of the semiconductor portion (4). A short circuit between the upper electrode (5) and the substrate (1) serving as a lower electrode which is caused by the semiconductor portion (4) can be prevented by providing the separation portion (6). Therefore, the photoelectric conversion device can have high conversion efficiency and high productivity.

### BACKGROUND OF THE INVENTION

1. Field of the Invention

The present invention relates to a photoelectric conversion device, such as a solar cell, using crystalline semiconductor particles, and relates to a method for manufacturing the device.

2. Description of the Related Art

Practical use has been conventionally made of a solar cell that uses crystalline silicon wafers and that has high conversion efficiency. The crystalline silicon wafers are produced by being cut out from a large sized single-crystal silicon ingot that is superior in crystallinity, that has fewer impurities, and that is well balanced in the distribution thereof. However, since much time is required to form the large sized single-crystal silicon ingot, productivity to be achieved is low, thus bringing about high costs. Therefore, it is intensely expected that a next-generation solar cell with high efficiency will appear without needing such a large-sized single-crystal silicon ingot.

For example, a photoelectric conversion device that uses silicon crystalline particles shown in FIG. 6 has been proposed as a photoelectric conversion device not needing a large-sized single-crystal silicon ingot. This photoelectric conversion device is structured as follows. A low-melting point metallic layer 108 is formed on a substrate 101, and a plurality of semiconductor particles 103 of one conductivity type are disposed on the low-melting point metallic layer 108. These semiconductor particles 103 are fixed by heating the low-melting point metallic layer 108. An insulator 102 is formed in such a way as to fill up gaps between the fixed semiconductor particles 103 and so as to cover the semiconductor particles 103 and the low-melting point metallic layer 108. The semiconductor particles 103 of one conductivity type are then exposed by grinding a part of the insulator 102 formed on the semiconductor particles 103. A semiconductor portion 104 of an opposite conductivity type and a transparent conductive layer 106 are successively formed on the surface of the exposed semiconductor particles 103.

Likewise, a photoelectric conversion device shown in FIG. 7 is proposed as a photoelectric conversion device that uses silicon crystalline particles. This photoelectric conversion device is structured as follows. An insulator 102 not yet hardened is formed on a graphite substrate (not shown), and semiconductor particles 103 of one conductivity type are disposed in such a way as to bury a part of each semiconductor particle 103 therein. After hardening the insulator 102, a connection layer 110 made of aluminum paste is formed in such a way as to cover the insulator 102 and the semiconductor particles 103 exposed from the insulator 102. After additionally forming a substrate 101 that serves as a lower electrode, the graphite substrate (not shown) is peeled off. The surface of the insulator 102 from which the graphite substrate has been peeled off is then ground to expose the semiconductor particles 103 of one conductivity type. A semiconductor portion 104 of the opposite conductivity type and a transparent conductive layer 106 are successively formed on a surface resulting from exposing the semiconductor particles 103.

However, these conventional photoelectric conversion devices shown in FIG. 6 and FIG. 7 have a problem as follows. The semiconductor portion 104 of the opposite conductivity type is formed on the surface of the semiconductor particles 103 of one conductivity type that have been exposed by being ground together with the insulator 102, an, as a result, pn junctions are formed. Therefore, damage, such as a crystal fault, is left on the pn junction interface because of the grinding operation, whereby the quality of the pn junction is lowered. Accordingly, a new energy level resulting from, for example, a crystal fault is formed between a valence band and a conduction band in a pn junction area. As a result, conversion efficiency is lowered.

The conventional photoelectric conversion devices have another problem in the fact that a precision grinding process is required to form an excellent exposed surface for all of the semiconductor particles 103 by a grinding operation, and therefore it is difficult to produce such a surface, and high productivity cannot be achieved.

### BRIEF SUMMARY OF THE INVENTION

It is an object of the present invention to provide a photoelectric conversion device that has high conversion efficiency and that is superior in productivity, and provide a method for manufacturing the device.

The photoelectric conversion device of the present invention is constructed such that a plurality of crystalline semiconductor particles of one conductivity type, which is formed so that a semiconductor portion of the opposite conductivity type is disposed on a surface of the crystalline semiconductor particles, are joined onto a substrate serving as a lower electrode. The substrate and the semiconductor portion are arranged apart from each other. An insulator is formed between the crystalline semiconductor particles so as to cover a surface of the substrate and a lower part of the semiconductor portion and so as to expose an upper part of the semiconductor portion, and, as a result, an upper electrode is formed while covering the insulator and the upper part of the semiconductor portion.

Since this photoelectric conversion device has the substrate serving as a lower electrode and the semiconductor portion arranged separated from each other, and electric current can be prevented from short-circuiting from the upper electrode to the lower electrode through the semiconductor portion, and this photoelectric conversion device can have high conversion efficiency.

Additionally, if the semiconductor portion is formed in the vicinity of the joint area contiguous to the substrate, a wide pn junction area can be taken in the surface of the upper half of the crystalline semiconductor particle and in the surface of the lower half thereof excluding the joint area, and light that has passed through the insulator is reflected by the substrate and is caused to be made incident on the pn junction area, thus making it possible to perform efficient photoelectric conversion. Therefore, the photoelectric conversion device of the present invention can have high conversion efficiency.

Preferably, the area of the separation portion is ⅕ or less than the surface area of the semiconductor particles where a photoelectric conversion is performed. The reason is that there is a fear that a dangling bond formed on the surface of the crystalline semiconductor particle 3 will promote the recombination of carriers on the surface of the crystalline semiconductor particle if the area of the separation portion exceeds ⅕ of the surface area of the semiconductor particle where a photoelectric conversion is performed.

Preferably, in the above-mentioned structure, the photoelectric conversion device of the present invention is formed so that the surface of the crystalline semiconductor particle and the surface of the semiconductor portion are roughened-surfaces.

If the surface of the crystalline semiconductor particle and the surface of the semiconductor portion are rough, part of the light that has been made incident on the semiconductor particle performing a photoelectric conversion is repeatedly reflected on a slant surface forming the roughened surface and is taken into the semiconductor particle. Therefore, the light can be guided to pn junction areas, and the photoelectric conversion device of the present invention can have high conversion efficiency. The repeated reflections produce both the effect of repeated reflections in a semiconductor particle where a photoelectric conversion is performed and the effect of repeated selections between semiconductor particles where two or more photoelectric conversion are performed. Additionally, since the insulator is buried in concave parts of a semiconductor particle performing a photoelectric conversion as if to drive wedges into the concave parts, firmer adhesion is established between the semiconductor particle and the substrate (which is called an “anchor effect”), and the photoelectric conversion device of the present invention can be formed as a photoelectric conversion device having high reliability. Likewise, firmer adhesion is established between the crystalline semiconductor particle and the semiconductor portion, and the photoelectric conversion device of the present invention can have high reliability.

Preferably, the arithmetic mean roughness (Ra) of the surface of the crystalline semiconductor particle ranges from 0.1 μm to 30 μm.

If the surface of the crystalline semiconductor particle is roughened surface having cone-like convex parts or concave parts, the light capturing effect and the anchor effect are heightened. Therefore, the photoelectric conversion device of the present invention becomes higher in conversion efficiency and in reliability. Especially, when the roughed surface is formed by non-uniform cone-like convex parts or concave parts, the light capturing effect and the anchor effect become even higher. Therefore, the photoelectric conversion device of the present invention becomes even higher in conversion efficiency and in reliability.

A method for manufacturing a photoelectric conversion device according to the present invention sequentially performs a step of joining junction areas of a plurality of crystalline semiconductor particles of one conductivity type to a substrate serving as a lower electrode; a step of forming a semiconductor portion of an opposite conductivity type on a surface of the crystalline semiconductor particle, excluding the junction areas; a step of forming a separation portion by removing material around an outer periphery of a joint area between the substrate and the crystalline semiconductor particle; a step of forming an insulator between the crystalline semiconductor particles on the substrate in a state of covering a surface of the substrate and a lower part of the semiconductor portion while exposing an upper part of the semiconductor portion; and a step of forming an upper electrode with which the insulator and the upper part of the semiconductor portion are covered.

According to this manufacturing method, since material around the outer periphery of the joint area between the substrate and the crystalline semiconductor particle is removed, the substrate and the semiconductor portion can be separated from each other without reducing the area of pn junctions. Therefore, it is possible to manufacture a photoelectric conversion device having high conversion efficiency.

Additionally, since pn junctions are formed before forming the insulator, there is no need to perform a step of grinding the insulator. Therefore, there never arises a decrease in the quality of pn junctions resulting from a defect caused by removing the insulator or resulting from contamination produced by allowing the insulator to adhere to the crystalline semiconductor particle or to the surface of the semiconductor portion of the opposite conductivity type. Therefore, the photoelectric conversion device of the present invention can become higher in conversion efficiency and in productivity.

In the step of forming a semiconductor portion of an opposite conductivity type on a surface of the crystalline semiconductor particle, it is permitted to form the semiconductor portion of the opposite conductivity type on the surface of the crystalline semiconductor particle according to a thermal diffusion method. According to this method, the semiconductor portion can be easily formed on the surface of the crystalline semiconductor particle without using a large-scale vacuum apparatus. Therefore, high productivity can be achieved.

Preferably, wet etching is performed in the step of forming a separation portion by removing matter around an outer periphery of a joint area between the substrate and the crystalline semiconductor particle. Through the wet etching process, the semiconductor portion and the substrate can be easily separated from each other without using a large-scale apparatus.

If the surface of the crystalline semiconductor particle is roughened before performing the step of joining the plurality of crystalline semiconductor particles of one conductivity type to the substrate serving as a lower electrode, the surface thereof can be roughened without causing defects in the joint area between the substrate and the crystalline semiconductor particle and in the substrate, and the crystalline semiconductor particle can be satisfactorily washed after the roughening step, in comparison with a case in which the surface of the crystalline semiconductor particle is roughed after the substrate and the crystalline semiconductor particle are joined together. Therefore, there never arises deterioration in the quality of pn junctions that is caused by contamination, such as residues of an etchant or smudges, resulting from the surface roughening step. Therefore, it is possible to manufacture a photoelectric conversion device having high conversion efficiency.

Additionally, since the surface of the crystalline semiconductor particle is a roughened surface, the crystalline semiconductor particle can be easily fixed closely to the substrate when the substrate and the crystalline semiconductor particles are joined together. Therefore, the photoelectric conversion device of the present invention can be easily manufactured.

Additionally, when a semiconductor portion is produced according to a thin-film-forming method, the thickness of a lower part of the semiconductor portion can be reduced on the side of the joint area, because the existence of the roughened surface makes it difficult that a carrier gas flows around. Therefore, it is possible to prevent the generation of a leakage current that flows from the upper electrode to the substrate serving as a lower electrode through the semiconductor portion. Therefore, a photoelectric conversion device with high conversion efficiency can be manufactured.

Preferably, the step of roughening the surface of the crystalline semiconductor particle is performed by etching that uses a mixed solution obtained by mixing and heating an alkaline aqueous solution and an antifoaming agent together. Since the surface of the crystalline semiconductor particle has various plane directions, non-uniform cone-like convex or concave parts are formed when the surface of the crystalline semiconductor particle is roughened in the mixed solution obtained by mixing and heating an alkaline aqueous solution and an antifoaming agent together. Therefore, the light capturing effect and the anchor effect become higher, and it is possible to manufacture a photoelectric conversion device that is high in conversion efficiency and in reliability.

### BRIEF DESCRIPTION OF THE DRAWINGS

FIG. 1 in a sectional view showing an embodiment of the photoelectric conversion device of the present invention.

FIGS. 2(a) to 2(c) are sectional views, each showing an example of the formation of a separation portion in the photoelectric conversion device of the present invention.

FIGS. 3(a) to 3(e) are sectional views, each explaining steps of a method for manufacturing the photoelectric conversion device of the present invention.

FIGS. 4(a) to 4(c) are sectional views, each explaining steps of another method for manufacturing the photoelectric conversion device of the present invention.

FIG. 5 is a sectional view showing another embodiment of the photoelectric conversion device of the present invention.

FIG. 6 is a sectional view showing an example of a conventional photoelectric conversion device.

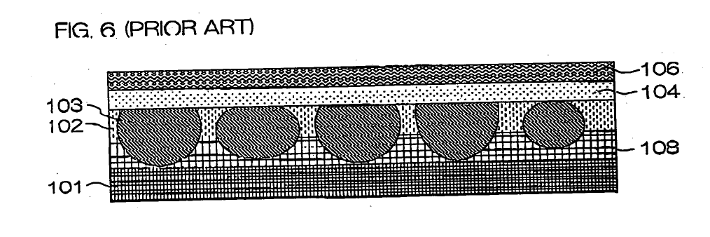

FIG. 7 is a sectional view showing another example of the conventional photoelectric conversion device.

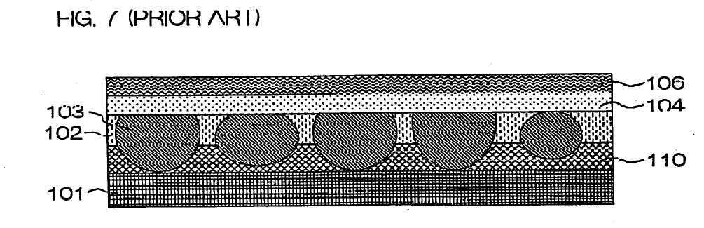

### DETAILED DESCRIPTION OF THE INVENTION

The present invention will be hereinafter described in detail with reference to the attached drawings.

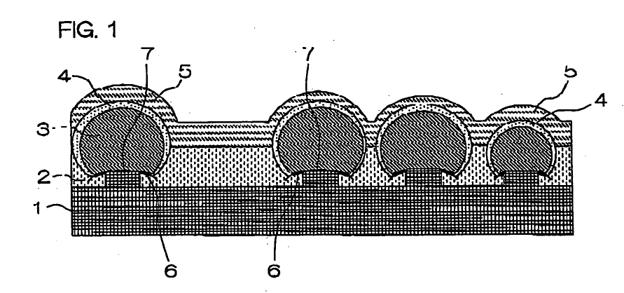

FIG. 1 is a sectional view showing an embodiment of the photoelectric conversion device of the present invention.

In FIG. 1, reference numeral 1 designates a substrate serving as a lower electrode, reference numeral 2 designates an insulator, reference numeral 3 designates a crystalline semiconductor particle of one conductivity type, reference numeral 4 designates a semiconductor portion of the opposite conductivity type formed on the surface of the semiconductor particle, and reference numeral 5 designates an upper electrode. Reference numeral 6 designates a portion (hereinafter, referred to as a “separation portion”) formed to separate the substrate 1 and the semiconductor portion 4 from each other.

As shown in FIG. 1, the photoelectric conversions device of the present invention has a plurality of crystalline semiconductor particles 3 joined onto the substrate 1. The area in which the crystalline semiconductor particle 3 is joined onto the substrate 1 is referred to as a “joint area 7.”

The crystalline semiconductor particle 3 has a structure in which the semiconductor portion 4 of the opposite conductivity type (for example, n-type) is formed on the surface of the semiconductor particle 3 of one conductivity type (for example, p-type), excluding the joint area 7 and the separation portion 6. Gaps between the adjoining semiconductor particles 3 are filled with the insulator 2 in such a way as to cover the substrate 1 and so as to expose the upper part of the semiconductor portion 4. The upper electrode 5 is formed by covering the insulator 2 and the upper part of the semiconductor portion 4.

In the photoelectric conversion device shown in FIG. 1, the crystalline semiconductor particle 3 is structured such that the semiconductor portion 4 is formed on the whole surface of the upper half of the semiconductor particle 3 and in the vicinity of the joint area 7 of the lower half of the semiconductor particle 3 joined to the substrate 1.

The separation portion 6 is defined to be a partial area of the crystalline semiconductor particle 3 between the joint area 7 and the semiconductor portion 4.

Metal, glass, ceramics, or resin is used as the substrate 1. Preferably, metal, such as silver (Ag), aluminum (Al), or copper (Cu), that is superior in conductivity and in reflectivity is used. The reason why metal having high reflectivity is preferred is that the use of the substrate 1 having a high degree of reflection makes it possible to guide a large quantity of light reflected from the substrate 1 toward a pn junction area of the semiconductor particle where a photoelectric conversion is performed, thus improving conversion efficiency.

If an insulator is used as the substrate 1, it is necessary to form a conductive layer serving as a lower electrode on the surface of the substrate 1. Preferably, this conductive layer is also made of a material, such as silver, aluminum, or copper, that is high in optical reflectance and in electric conductivity, in order to guide a large quantity of light reflected from the substrate 1 toward a pn junction area of the semiconductor particle where a photoelectric conversion is performed.

The insulator 2 is made of an insulating material that performs separation between positive and negative electrodes. It is recommended to use a low-temperature firing glass material chiefly composed of arbitrary components selected from, for example, SiO₂, B₂O₃, Al₂O₃, CaO, MgO, P₂O₅, Li₂O, SnO₂, ZnO, BaO, TiO₂, a glass composition combined with a filler composed of one or more arbitrary combinations of these components, a heat-resistant resinous material such as epoxy resin or polyimide resin, an inorganic/organic composite material, etc.

Preferably, the optical transmittance of the insulator 2 is 70% or more under the condition where the wavelength ranges from 400 nm to 1200 nm. The reason is that, if the optical transmittance is lower than 70%, the quantity of light guided to a pn junction area of the semiconductor particle where a photoelectric conversion is performed will be reduced, thus lowering the conversion efficiency.

After the crystalline semiconductor particle 3 on which the semiconductor portion 4 has been formed is joined to the substrate 1, the insulator 2 is formed on the substrate 1 in such a way as to be buried between the semiconductor particles.

The semiconductor portions 4 are connected together by the upper electrode 5.

The photoelectric conversion device of the present invention is manufactured in this way through a step in which the crystalline semiconductor particle 3 is joined to the substrate 1 before being filled with the insulator 2.

A conventional manufacturing method is carried out such that the insulator 2 is first formed on the substrate 1, the substrate 1 is then heated to a high temperature, and the crystalline semiconductor particle 3 is pressed to the substrate 1 from above the insulator 2. According to this conventional method, there is a case in which the insulator 2 adheres to the surface of the semiconductor particle 3 and to the semiconductor portion 4, whereby the semiconductor particle 3 and the semiconductor portion 4 are contaminated. However, according to the present invention, the crystalline semiconductor particle 3 is joined to the substrate 1 before being filled with the insulator 2, and therefore, unlike the conventional method, there never arises a fear that the crystalline semiconductor particle 3 and the semiconductor portion 4 will be contaminated. Therefore, since there is not a case in which deterioration in the quality of pn junctions is caused by this contamination, high conversion efficiency can be achieved. Additionally, since a grinding step for removing the insulator 2 is not required, productivity is improved.

The crystalline semiconductor particle 3 is made of silicon (Si), germanium (Ge), etc. The crystalline semiconductor particle 3 contains boron (B), aluminum (Al), and antimony (Sb) used as p-type impurities, or contains phosphorus (P) and arsenic (As) used as n-type impurities. For example, boron and aluminum, which are p-type impurities, are added at the rate of about 1×10¹⁴ to 1×10¹⁸ atoms/cm³ if the semiconductor particle 3 is the p-type. The crystalline semiconductor particle 3 can be formed according to a vapor growth method, an atomizing method, a direct current plasma method, or a melt dropping method. Preferably, the melt dropping method in which a melt is dropped in a non-contact environment is employed because productivity is high, and cost is low. Preferably, the crystalline semiconductor particle 3 is monocrystalline in order to improve photoelectric conversion efficiency although either a monocrystalline substance or a polycrystalline substance can be used.

The semiconductor portion 4 is made of a material obtained by adding trace elements to silicon, germanium, etc., so as to have a conductivity type opposite to that of the semiconductor particle 3. For example, the semiconductor portion 4 contains phosphorous and arsenic, which are n-type impurities added to silicon, if the semiconductor particle 3 is the p-type.

Preferably, the thickness of the semiconductor portion 4 ranges from 5 nm to 5000 nm at its zenith part. The reason is that, if the thickness of the semiconductor portion 4 is less than 5 nm, the semiconductor portion 4 is isolated like an island, whereby defective parts in covering are produced in the semiconductor portion 4, and, if the thickness of the semiconductor portion 4 exceeds 5000 nm, photoabsorption becomes large in the semiconductor portion 4, whereby conversion efficiency is lowered. The semiconductor portion 4 is not necessarily required to be uniform in thickness. Herein, the term “zenith part” denotes the highest point of the crystalline semiconductor particle 3.

The semiconductor portion 4 may be any one of a monocrystalline substance, a polycrystalline (or multi-crystalline) substance, and amorphous substance, a microcrystalline substance, and a nanocrystalline substance. Herein, the microcrystalline substance denotes a substance composed of crystal grains whose grain diameter ranges, for example, from 0.1 μm to less than 50 μm, and the nanocrystalline substance denotes as a substance composed of crystal grains whose grain diameter ranges, for example, from 1 nm to less than 50 nm. Preferably, the semiconductor portion 4 is monocrystalline of polycrystalline because photoabsorption can be reduced in the semiconductor portion 4, and conversion efficiency is improved.

This semiconductor portion 4 may be formed using a method for producing a thin film on the surface of the crystalline semiconductor particle 3 according to a plasma CVD (Chemical Vapor Deposition) method, a catalyst CVD method, or a sputtering method. Alternatively, the semiconductor portion 4 may be formed at a part having a predetermined depth from the surface of the crystalline semiconductor particle 3 according to an ion implantation method of a thermal diffusion method. It is especially preferable to employ the “thermal diffusion method” in which a dopant is thermally diffused into the crystalline semiconductor particle 3 by being heated in a gas containing the dopant. The reason is that the thermal diffusion method makes it possible to form the uniform semiconductor portion 4 at the outer hull of the semiconductor particle 3 with high productivity without needing a large-scale vacuum apparatus.

Preferably, a material having high optical transmittance is used as a material of the upper electrode 5 so as not to absorb light under the condition where the wavelength ranges from 400 nm to 1200 nm. Herein, the material having high optical transmittance is a material whose optical transmittance is, for example, 70% or more. A tin oxide, an indium oxide, etc., can be mentioned as the material having high optical transmittance.

Preferably, the thickness of the upper electrode 5 ranges from 50 nm to 300 nm. The reason is that, if the thickness of the upper electrode 5 is less than 50 nm, resistance is heightened, and conversion efficiency is lowered, which is undesirable. On the other hand, if the thickness of the upper electrode 5 exceeds 300 nm, light is absorbed by the upper electrode 5, and the quantity of light guided to a pn junction area of the semiconductor particle where a photoelectric conversion is performed is lowered so as to lower conversion efficiency, which is undesirable.

It is recommended to form the upper electrode 5 while using the above-mentioned materials according to the sputtering method, the plasma CVD method, or the catalyst CVD method. At this time, the upper electrode 5 can also be provided with an antireflection effect by adjusting the thickness and refractive index of the above-mentioned materials.

An auxiliary electrode may be additionally formed thereon with an appropriate pattern using a silver past or copper paste.

When viewed cross-sectionally, the separation portion 6 annularly exists so as to electrically separate the substrate 1 serving as a lower electrode from the semiconductor portion 4 and so as to enclose a joint area between the crystalline semiconductor particle 3 and the substrate 1. The existence of the separation portion 6 makes it possible to prevent a short circuit between the upper electrode 5 and the substrate 1 serving as a lower electrode by means of the semiconductor portion 4, and conversion efficiency is improved, which is preferable.

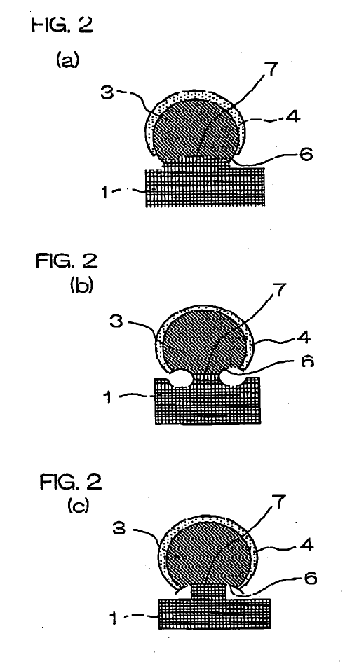

FIGS. 2(a) to 2(c) are sectional views, each showing a forming example of the separation portion 6 in the photoelectric conversion device of the present invention.

As shown in FIGS. 2(a) to 2(c), the separation portion 6 is formed by removing the matter around the outer periphery of the joint area between the substrate 1 and the crystalline semiconductor particle 3.

FIG. 2(a) shows an example in which the substrate 1 and the crystalline semiconductor particle 3 are first joined together, and then a part of the semiconductor portion 4 is formed only on an upper surface of the semiconductor particle 3 so that the semiconductor portion 4 does not come into contact with the lower surface of the semiconductor particle 3 so as to form the separation portion 6.

FIG. 2(b) shows an example in which the substrate 1 and the crystalline semiconductor particle 3 are first joined together, and then both a part around the outer periphery of the crystalline semiconductor particle 3 and a part of the outer periphery of the substrate 1 are removed.

FIG. 2(c) shows an example in which the substrate 1 and the crystalline semiconductor particle 3 are first joined together, and then a part around the outer periphery of the crystalline semiconductor particle 3 on the side of the substrate 1 is removed.

In the example of FIG. 2(c) in which the matter around the outer periphery of the joint area on the side of the substrate 1 is removed to form the separation portion 6, a part of a pn junction formed on the surface of the crystalline semiconductor particle 3 is not removed. Therefore, the area of the pn junction area can be greatly taken, and the photoelectric conversion device can have high conversion efficiency.

In the example of FIG. 2(b), the surface layer of the substrate 1 is removed as well as the outer periphery of the joint area, and therefore separation can be realized more reliably.

Preferably, the area of the separation portion 6 is ⅕ or less than the surface area of the semiconductor particle at which a photoelectric conversion is performed. The reason is that, if the area of the separation portion 6 exceeds ⅕ of the surface area of the semiconductor particle where a photoelectric conversion is performed, the recombination of carriers on the surface of the crystalline semiconductor particle 3 will be advanced by a dangling bond formed on the surface of the crystalline semiconductor particle 3, and characteristics will deteriorate greatly. However, even if the area of the separation portion 6 exceeds ⅕ of the surface area of the crystalline semiconductor particle 3 performing a photoelectric conversion, the dangling bond can be ended by passivating the separation portion 6 with an oxide film or the like, and, as a result, the recombination on the surface of the crystalline semiconductor particle 3 is prevented. Therefore, a high photoelectric conversion rate can be maintained.

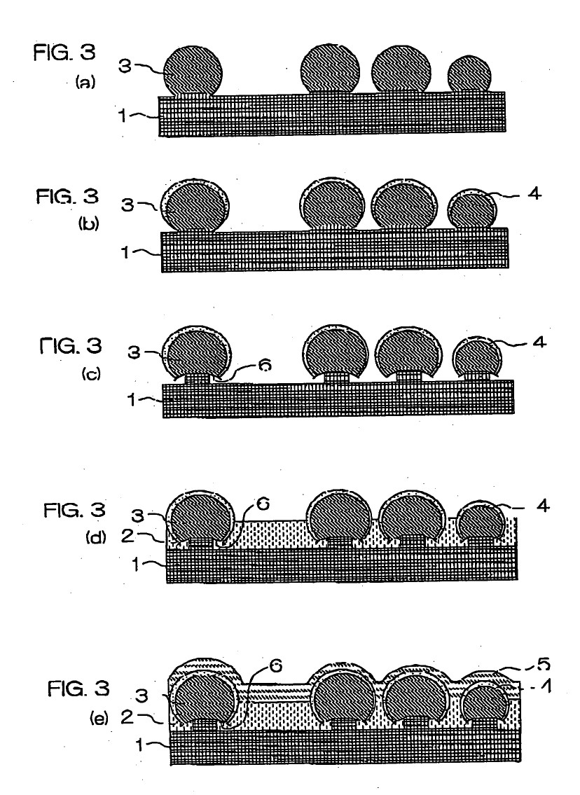

Next, a description will be given of a method for manufacturing the photoelectric conversion device in FIG. 2(a) of the present invention referring to FIGS. 3(a) to 3(e).

FIGS. 3(a) to 3(e) are sectional views showing steps of manufacturing the photoelectric conversion device of the present invention.

First, a layer of a plurality of crystalline semiconductor particles 3 are closely arranged on the substrate 1, these are then heated on the whole, and the substrate 1 and the crystalline semiconductor particle 3 are joined together, as shown in FIG. 3(a). It is permitted to heat and join the substrate 1 and the crystalline semiconductor particle 3 together while applying a load from above the plurality of crystalline semiconductor particles 3 closely arranged on the substrate 1.

Thereafter, the semiconductor portion 4 is formed on the surface of the crystalline semiconductor particle 3, as shown in FIG. 3(b). If the crystalline semiconductor particle 3 is the p-type at this time, the semiconductor portion 4 is formed to be the n-type, and, if the crystalline semiconductor particle 3 is the n-type, the semiconductor portion 4 is formed to be the p type.

The semiconductor portion 4 may be formed according to a diffusion method or plasma CVD method by applying a dopant to the surface of the crystalline semiconductor particle 3, or may be formed on the surface of the crystalline semiconductor particle 3 according to an epitaxial method.

Thereafter, a joint area between the substrate 1 and the crystalline semiconductor particle 3 is exposed by removing a surface part of the substrate 1 to a predetermined depth from the surface of the substrate 1, as shown in FIG. 3(c). As a result, the substrate 1 and the semiconductor portion 4 can be electrically separated from each other. Since only a part of the substrate 1 is removed in this way without removing the semiconductor portion 4 in the vicinity of the joint area between the substrate 1 and the crystalline semiconductor particle 3, pn junctions having a greater area can be obtained.

A wet etching process or a dry etching process that is carried out by forming a mask by the use of a photoresist can be mentioned as a process for removing a part of the substrate 1 ranging from the surface of the substrate 1 to a predetermined depth. Preferably, the wet etching process is employed to remove the predetermined depth, because the substrate 1 can be selectively etched, and high productivity can be achieved.

The area of the separation portion 6 existing after removing the substrate part can be easily controlled by the etching rate of the substrate 1 serving as a lower electrode. It is required of an etchant used in the wet etching process to make the etching rate of the substrate 1 higher than the etching rate of the crystalline semiconductor particle 3 and than that of the semiconductor portion 4. For example, if the crystalline semiconductor particle 3 and the semiconductor portion 4 are made of silicon and if the substrate 1 is made of aluminum, it is preferable to use hydrochloric acid, hydrofluoric acid, nitric acid, sulfuric acid, phosphoric acid, sodium hydroxide, or potassium hydroxide. It is permitted to provide a protective layer on the surface of the crystalline semiconductor particle 3 and the surface of the semiconductor portion 4, in order to protect the semiconductor portion 4 from damage and contamination caused by etching when the wet etching process is carried out. It is recommended to form an oxide film or a nitride film as the protective layer.

Alternatively when the semiconductor portion 4 of the opposite conductivity type is formed on the crystalline semiconductor particle 3, ion implantation or ion plating method can be used by adding a bias potential on the substrate 1. With applying a dopant in perpendicular direction into the substrate 1, the semiconductor portion 3 is formed only on an upper surface of the semiconductor particle 3, so that the semiconductor portion 4 does not come into contact with the lower surface of the semiconductor particle 3 so as to form the separation portion 6.

Thereafter, the insulator 2 is formed on the substrate 1 is such a way as to fill gaps between the adjoining semiconductor particles 3 at which a photoelectric conversion is performed, as shown in FIG. 3(d). At this time, the quantity of the insulator 2 is adjusted to expose the upper part of the semiconductor portion 4.

Further, as shown in FIG. 3(e), the upper electrode 5 is formed in such a way as to cover the insulator 2 and the upper part of the semiconductor portion 4, whereby the photoelectric conversion device of the present invention shown in FIG. 1 can be obtained.

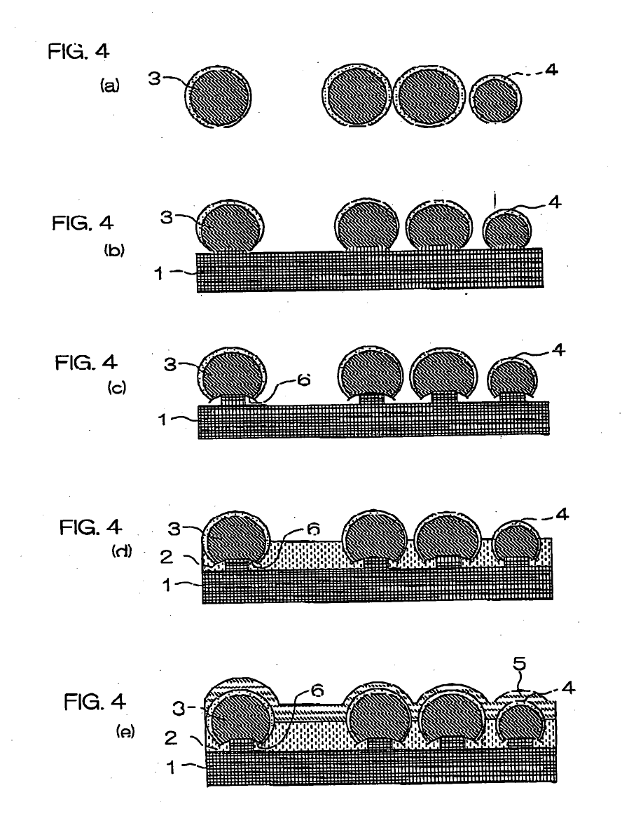

A description will now be given of another method for manufacturing the photoelectric conversion device in FIG. 2(c) of the present invention referring to FIGS. 4(a) to 4(c).

FIGS. 4(a) to 4(c) are sectional views showing another process for manufacturing the photoelectric conversion device of the present invention.

First, the crystalline semiconductor particle 3 is heated in a gas containing a dopant so as to have conductivity opposite to that of the crystalline semiconductor particle 3, the dopant is then thermally diffused into the crystalline semiconductor particle 3, and the semiconductor portion 4 is formed on the outer hull of the crystalline semiconductor particle 3, as shown in FIG. 4(a). Herein, the thickness of the semiconductor portion 4 can be controlled by a heating temperature and a processing time.

Thereafter, a layer of a plurality of crystalline semiconductor particles 3 are closely arranged on the substrate 1, these are then heated on the whole, and the substrate 1 and the crystalline semiconductor particle 3 are joined together, as shown in FIG. 4(b). Since an alloy of the substrate 1 and the crystalline semiconductor particle 3 is formed in the joint area by heating and joining the substrate 1 and the crystalline semiconductor 3 together, the semiconductor portion 4 disappears from the joint area between the substrate 1 and the crystalline semiconductor particle 3. The substrate 1 and the crystalline semiconductor particle 3 can also be joined together after removing the semiconductor portion 4 in the joint area of the crystalline semiconductor particle 3.

Thereafter, as shown in FIG. 4(c), by removing a predetermined depth from the surface of the substrate 1, to form the separation portion 6 so that the connecting portion of the substrate 1 and the crystalline semiconductor particle 3 is exposed. Then, the exposed portion is etched by wet etchant of the crystalline semiconductor particle 3, for example, by hydrofluoric nitric acid to silicon if the semiconductor particle 3 is made of silicon. Then, the substrate 1 and the crystalline semiconductor particle 3 is etched in a thin depth, and particularly the exposed portion of an acute angle is etched deeply with compared to the other portions, the separation portion can be formed definitely to electrically separate the substrate 1 and the semiconductor portion 4.

The insulator 2 and the upper electrode 5 are formed on the crystalline semiconductor particle 3 joined to the substrate 1 in this way as shown in FIGS. 4(d) and 4(e) in the same way as in the manufacturing method of the photoelectric conversion device described referring to FIGS. 3(a) to 3(e), whereby the photoelectric conversion device of the present invention shown in FIG. 1 can be obtained.

As described above, the photoelectric conversion device of the present invention shown in FIG. 1 has a structure in which a plurality of crystalline semiconductor particles 3, each of which is provided with the semiconductor portion 4 of the opposite conductivity type on its surface, are joined onto the substrate 1 serving as a lower electrode, and in which the substrate 1 and the semiconductor portion 4 are arranged in a state of being separated from each other by the separation portion 6. The insulator 2 is formed between the crystalline semiconductor particles 3 while covering the surface of the substrate 1 and the lower part of the semiconductor portion 4 and exposing the upper part of the semiconductor portion 4. The upper electrode 5 is formed covering the insulator 2 and the upper part of the semiconductor portion 4.

In the structure of FIG. 1, the formation of the separation portion 6 makes it possible to prevent the short circuit of an electric current flowing from the upper electrode 5 to the substrate 1 serving as a lower electrode through the semiconductor portion 4. Therefore, the photoelectric conversion device of the present invention can have high conversion efficiency.

Additionally, since the semiconductor portion 4 is formed also on the surface of the lower half of the crystalline semiconductor particle 3, it is possible to obtain a larger area for pn junctions where a photoelectric conversion is performed, and the photoelectric conversion device of the present invention can have high conversion efficiency.

Additionally, since the influence of a recombination in the operation portion 6 can be reduced by setting the area of the separation portion 6 to be ⅕ or less than the surface area of the semiconductor particle where a photoelectric conversion is performed, it becomes possible to produce a photoelectric conversion device having high conversion efficiency.

Additionally, since a large quantity of light reflected from the substrate 1 is guided to a pn junction area of the semiconductor particle performing a photoelectric conversion by using a high-reflectance material for the substrate 1 in the structure of FIG. 1, the photoelectric conversion device of the present invention can have high conversion efficiency.

Additionally, since light can be efficiently guided to a pn junction area of the semiconductor particle performing a photoelectric conversion by making the insulator 2 out of a material having high optical transmittance, the photoelectric conversion device of the present invention can have high conversion efficiency.

Since a monocrystalline substance is used for the crystalline semiconductor particle 3, the photoelectric conversion device of the present invention can have high conversion efficiency.

Since a pn junction can be formed on the semiconductor particle without gaps, and photoabsorption can be reduced to efficiently guide light to the pn junction area by forming the thickness of the semiconductor portio 4 so as to range from 5 nm to 5000 nm, the photoelectric conversion device of the present invention can have high conversion efficiency.

Since photoabsorption can be reduced by making the semiconductor portion 4 out of a monocrystalline substance or a polycrystalline substance, and since light can be efficiently guided to the pn junction area of the semiconductor particle performing a photoelectric conversion thereby, the photoelectric conversion device of the present invention can have high conversion efficiency.

Additionally, light can be efficiently guided to the pn junction area of the semiconductor particle performing a photoelectric conversion, and resistance can be lowered by making the upper electrode 5 out of a material having high optical transmittance and by forming the thickness of the upper electrode 5 so as to range from 50 nm to 300 nm. Therefore, the photoelectric conversion device of the present invention can have high conversion efficiency.

According to the manufacturing method of the photoelectric conversion device of the present invention, the separation portion 6 is formed after the crystalline semiconductor particle 3 having the semiconductor portion 4 on its surface is joined to the substrate 1. Therefore, a short circuit can be reliably and easily prevented between the upper electrode 5 and the substrate 1 serving as a lower electrode, and it is possible to produce a photoelectric conversion device having high conversion efficiency.

A photoelectric conversion device having high conversion efficiency can be produced by removing matter around the outer periphery of a joint area between the substrate 1 and the crystalline semiconductor particle 3 on the side of the substrate 1 and by forming the separation portion 6 without decreasing the area of pn junctions.

Additionally, according to the manufacturing method of the photoelectric conversion device of the present invention, the semiconductor portion 4 is formed according to the thermal diffusion method. Therefore, the semiconductor portion 4 can be formed to be uniform without needing a large scale vacuum apparatus, and the photoelectric conversion device of the present invention can be manufactured with high productivity.

Additionally, the separation portion 6 is formed through a wet etching process using hydrochloric acid, hydrofluoric acid, nitric acid, sulfuric acid, phosphoric acid, sodium hydroxide, or potassium hydroxide, and the matter around the outer periphery of the joint area on the side of the substrate 1 is removed. Thus, the substrate 1 and the semiconductor portion 4 can be reliably and easily separated from each other, and a photoelectric conversion device having high conversion efficiency can be easily manufactured.

The surface of the crystalline semiconductor particle 3 may be roughened. In this case, incident light thereon is multi-reflected and can be captured in to the semiconductor particle performing a photoelectric conversion with high efficiency. Therefore, high conversion efficiency can be obtained.

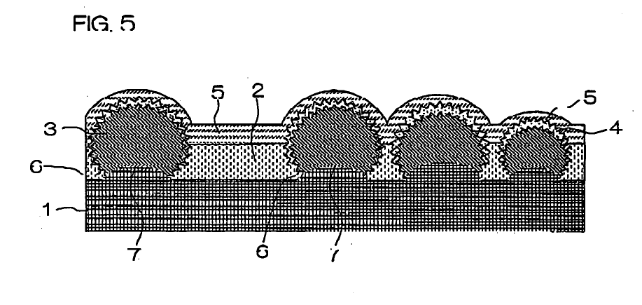

FIG. 5 is a sectional view showing another embodiment of the photoelectric conversion device of the present invention. The difference between the photoelectric conversion device of FIG. 5 and the photoelectric conversion device of FIG. 1 resides in the fact that the surface of the crystalline semiconductor particle 3 is roughened. One common feature between the photoelectric conversion device of FIG. 5 and the photoelectric conversion device of FIG. 1 is that the separation portion 6 exists for separating the substrate 1 and the semiconductor portion 4 from each other.

As shown in FIG. 5, the photoelectric conversion device of this embodiment has a structure in which a plurality of crystalline semiconductor particles 3 of one conductivity type (for example, p-type) whose surfaces are roughened are joined onto the substrate 1 serving as a lower electrode and in which the semiconductor potion 4 of the opposite conductivity type (for example, n-type) is formed on the surface of the crystalline semiconductor particle 3 excluding the joint area of the crystalline semiconductor particle 3. The insulator 2 is formed between the adjoining crystalline semiconductor particles 3 in such a way as to cover the surface of the substrate 1 and the lower part of the semiconductor portion 4 and so as to expose the upper part of the semiconductor portion 4. The upper electrode 5 is additionally formed to cover the insulator 2 and the upper part of the semiconductor portion 4.

Let the joint area of the crystalline semiconductor particle 3 be a required minimum are to be reliably joined to the substrate 1. The substrate 1 and the crystalline semiconductor particle 3 are joined together over the whole of the joint area of the crystalline semiconductor particle 3. In the photoelectric conversion device shown in FIG. 5, the semiconductor portion 4 is formed from the upper half of the crystalline semiconductor particle 3 to the joint area joining to the substrate 1 on the side of the lower half thereof.

As in the photoelectric conversion device of FIG. 1, the separation portion 6 annularly exists, when viewed cross-sectionally, so as to electrically separate the substrate 1 serving as a lower electrode from the semiconductor portion 4 and so as to enclose the joint area between the crystalline semiconductor particle 3 and the substrate 1. The existence of this separation portion 6 makes it possible to prevent the upper electrode 5 and the substrate 1 serving as a lower electrode from being short-circuited by the semiconductor portion 4.

The material of the substrate 1 is the same as the material described in the photoelectric conversion device of FIG. 1. When an insulator is used as the substrate 1, there is a need to form a conductive layer serving as a lower electrode on the surface of the substrate 1 in the same way as in the photoelectric conversion device of FIG. 1.

The material and optical transmittance of the insulator 2 are also formed in the same way as in the photoelectric conversion device of FIG. 1.

The crystalline semiconductor particle 3 is made of silicon (Si), germanium (Ge), etc. The semiconductor particle 3 contains boron (B), aluminum (Al), and antimony (Sb) used as p-type impurities, or contains phosphorus (P) and arsenic (As) used as n-type impurities. For example, boron and aluminum, which are p-type impurities, are added at the rate of about 1×10¹⁴ to 10¹⁰ atoms/cm³ if the semiconductor particle 3 is the p-type. The crystalline semiconductor particle 3 can be formed according to the vapor growth method, the atomizing method, the direct current plasma method, or the melt dropping method. Preferably, the melt dropping method in which a melt is dropped in a non-contact environment is employed because productivity is high, and cost is low.

The surface of the crystalline semiconductor particle 3 is a rugged, roughed surface.

When the crystalline semiconductor particle 3 is joined to the substrate 1, a frictional force becomes higher than a case in which the surface thereof is a specular surface, because the surface of the crystalline semiconductor particle 3 is a roughened surface. Therefore, the crystalline semiconductor particle can be easily fixed, and high productivity can be achieved.

Additionally, as a result of roughening the surface of the crystalline semiconductor particle 3, the surface of the semiconductor portion 4 formed on the surface of the crystalline semiconductor particle 3 also has the same rugged shape tracing the rugged contours of the crystalline semiconductor particle 3. Therefore, the conversion efficiency is improved by the light capturing effect, which is desirable. Additionally, the insulator 2 and the semiconductor particle performing a photoelectric conversion are closely joined together by the anchor effect, and reliability is improved, which is desirable. The “anchor effect” mentioned here means an effect by which the insulator 2 enters concave parts formed on the surface of the semiconductor particle performing a photoelectric conversion, and a shape is assumed as if to drive wedges into the semiconductor particle performing a photoelectric conversion, thereby improving the adhesion.

When the semiconductor portion 4 is formed on the surface of the crystalline semiconductor particle 3 that has been joined to the substrate 1 according to a thin-film producing technique, a carrier gas cannot easily flow around to the side of the joint area of the crystalline semiconductor particle 3, because the surface of the crystalline semiconductor particle 3 is a roughened surface. Therefore, the thickness of the semiconductor portion 4 can be reduced on the side of the joint area. Accordingly, resistance between the semiconductor portion 4 and the substrate 1 becomes larger, and it becomes possible to restrict a leakage current flowing from the upper electrode 5 to the substrate 1 serving as a lower electrode through the semiconductor portion 4, and, as a desirable result, conversion efficiency is improved.

In order to make a roughened surface, it is recommended to form an arbitrary rugged shape on the surface of the crystalline semiconductor particle 3. For example, a cylindrical convex or concave part may be formed thereon. However, it is preferable to form especially a cone-like convex or concave part. The reason is that the cone-like convex or concave part is larger in the light capturing effect and in the anchor effect than the columnar convex or concave part. Additionally, an optical path length is increased by forming a cone-like, non-uniform convex or concave part. Accordingly, like light capturing effect is heightened, and the insulator 2 and the semiconductor particle performing a photoelectric conversion are joined together with complex contours, and, as a desirable result, the anchor effect is heightened. The cone-like shape mentioned here is an angularly conic shape, a circularly conic shape, and elliptically conic shape, a shape obtained by dulling the end or ridge of these various cones, or a shape obtained by combining these cones together.

Herein, preferably, “Arithmetic Mean Deviation of the Surface (Ra)” concerning the surface of the crystalline semiconductor particle 3 ranges from 0.1 μm to 30 μm. “Arithmetic Mean Deviation of the Surface (Ra)” expresses a value obtained by the following equation in the form of “micro meter (μm)”
Ra=(1/L)∫|f(x)|dx
where ∫ (integration) ranges from x=0 to x−L, and |f(x)↑ is an absolute value of distance from the mean line to the profile, on the condition where the surface profile of the crystalline semiconductor particle 3 is extracted along its surface by a reference length L, and X axis is set in a direction in which the surface of the extracted part is extended, a Y axis is set in a direction perpendicular to the surface of the crystalline semiconductor particle 3, and a roughness curve is expresses as y=f(x).

When “Arithmetic Mean Deviation of the Surface” (Ra) is less than 0.1 μm, the light capturing effect and the anchor effect are lessened, and an effect by which a carrier gas cannot easily flow around to the side of the joint area of the crystalline semiconductor particle 3 is small when the semiconductor portion 4 is formed by the thin-film producing method. On the other hand, when “Arithmetic Mean Deviation of the Surface” (Ra) exceeds 30 μm, the light capturing effect and the anchor effect are heightened, but the semiconductor portion 4 cannot be formed deep into the concave part of the crystalline semiconductor particle 3, and covering-defective parts or gaps between the crystalline semiconductor particle 3 and the semiconductor portion 4 are generated.

Preferably, the crystalline semiconductor particles 3 are formed by a small number (for example, three or less) of crystal grains. Preferably, the crystal form of the crystal grain is monocrystalline or twin-crystalline. The reason is that, if the crystalline semiconductor particles 3 are formed by a large number (for example, four or more) of crystal grains, a deep groove is generated in a grain boundary, or a plurality of pits resulting from crystal defects are generated when a cone-like convex or concave part is formed on the surface of the crystalline semiconductor particle 3, and hence a pn junction area cannot be uniformly formed.

The semiconductor portion 4 is made of a material obtained by adding trace elements to silicon, germanium, etc., so as to have conductivity opposite to that of the crystalline semiconductor particle 3. The method for forming this is carried out in the same way as described with reference to FIG. 1.

According to the photoelectric conversion device shown in FIG. 5, the semiconductor portion 4 is also formed on the surface on the lower-half side of the crystalline semiconductor particle 3. Therefore, since light that has passed through the insulator 2 is reflected by the substrate 1 and is permitted to the pn junction area on the lower-half side of the semiconductor particle performing a photoelectric conversion, light to be made incident on the whole of the photoelectric conversion device can be efficiently and economically permitted to the pn junction area of the semiconductor particle performing a photoelectric conversion. Therefore, conversion efficiency can be raised.

Additionally, the surface of the semiconductor portion 4 has the same rough surface as that of the crystalline semiconductor particle 3 by following the rough contours of the surface of the crystalline semiconductor particle 3, and, as a desirable result, the light capturing effect and the anchor effect are heightened.

Preferably, the thickness of the zenith part of the semiconductor portion 4 ranges from 5 nm to 5000 nm. The reason is that, if the thickness of the zenith part of the semiconductor portion 4 is less than 5 nm, the semiconductor portion 4 is formed like an island, whereby defective parts in covering are produced in the semiconductor portion 4, and, if the thickness of the zenith part of the semiconductor portion 4 exceeds 5000 nm, a leakage current flowing to the substrate 1 serving as a lower electrode through the semiconductor portion 4 is increased, and photoabsorption becomes large in the semiconductor portion 4, whereby conversion efficiency is lowered.

The film quality of the semiconductor portion 4 may be any one of a monocrystalline substance, a polycrystalline substance, and amorphous substance, a microcrystalline substance, and a nonacrystalline substance. If the film quality of the semiconductor portion 4 is monocrystalline or polycrystalline, photoabsorption in the semiconductor portion 4 can be reduced, and, as a desirable result, conversion efficiency is improved. The semiconductor portion 4 is not necessarily required to be uniform in thickness.

Herein, since the photoelectric conversion device of the present invention has the crystalline semiconductor particle 3 whose surface has been roughened, a carrier gas cannot easily flow around in the vicinity of the joint area between the substrate 1 and the crystalline semiconductor particle 3 when the semiconductor portion 4 is formed according to the thin-film forming method. Therefore, the thickness of the lower part of the semiconductor portion 4 can be reduced on the side of the joint area.

The material and film thickness of the upper electrode 5 are identical with those described with reference to FIG. 1.

The manufacturing method of the photoelectric conversion device of the present invention will now be described taking the photoelectric conversion device of FIG. 5 as an example.

First, the surfaces of a plurality of crystalline semiconductor particles 3 are roughened by forming rugged contours on the surfaces thereof, for example, according to a sandblast method.

In particular, when the surface of the crystalline semiconductor particle 3 is roughened by forming cone-like convex or concave parts on the surface thereof, a dry etching method that uses RIE (Reactive Ion Etching) or a selection wet etching method that uses a sodium hydroxide (NaOH) aqueous solution or the like can be employed for roughening the surface thereof. Preferably, a wet etching method (hereinafter, referred to as a “thermal alkaline process”) that is carried out in a heated alkaline aqueous solution is employed, because cone-like convex and concave parts can be easily formed without needing a large scale apparatus.

Herein, the surface of the crystalline semiconductor particle 3 has various plane directions, and therefore non-uniform, cone-like convex or concave parts according to a combination of the plane directions are formed by performing the thermal alkaline process that is anisotropic etching.

The thermal alkaline process is to soak the crystalline semiconductor particles 3, for example, in an alkaline aqueous solution, such as NaOH, between 0.2% by weight and 30% by weight that has been heated to a temperature ranging from 40° C. to 95° C. for a period ranging from 1 minute to 100 minutes. More preferably, an alkaline aqueous solution heated to a temperature ranging from 60° C. to 90° C. is used. The reason is that, if the heating temperature of the alkaline aqueous solution is less than 60° C., the reaction velocity between the crystalline semiconductor particle 3 and the alkaline aqueous solution will become slow so as to lower productivity, and, if the heating temperature of the alkaline aqueous solution exceeds 90° C., the reaction between the crystalline semiconductor particle 3 and the alkaline aqueous solution will be rapidly advanced, and hence bubbles generated by the reaction cause the crystalline semiconductor particle 3 to rise to the solution level of the alkaline aqueous solution so as to generate a region that is not soaked in the alkaline aqueous solution, and, accordingly, the reaction does not progress in the whole surface.

Preferably, the concentration of the alkaline aqueous solution ranges from 0.5% by weight to 15% by weight. The reason is that, if the concentration of the alkaline aqueous solution is less than 0.5% by weight, the reaction velocity between the crystalline semiconductor particle 3 and the alkaline aqueous solution will become small so as to lower productivity, and, if the concentration of the alkaline aqueous solution exceeds 15% by weight, the reaction between the crystalline semiconductor particle 3 and the alkaline aqueous solution will be rapidly advanced, and hence bubbles as generated by the reaction cause the crystalline semiconductor particle 3 to rise to the solution level of the heated alkaline aqueous solution so as to generate a region that is not soaked in the alkaline aqueous solution, and, accordingly, the reaction does not progress in the whole of the surface. Herein, potassium hydroxide (KOH) or the like can be used as the alkaline aqueous solution, without being limited to NaOH.

Preferably, the thermal alkaline process is performed in a mixed solution obtained by mixing and heating an alkaline aqueous solution and an antifoaming agent together. The antifoaming agent is a substance having an action by which the wettability of the crystalline semiconductor particle 3 is improved, so that bubbles generated by the reaction between the crystalline semiconductor particle 3 and the alkaline aqueous solution can easily escape to the solution level. For example, alcohol, such as isopropyl alcohol (TPA), and a surface-active agent can be used as the antifoaming agent. The amount of addition of the antifoaming agent is set to range from about 0.1% by weight to 10% by weight. The reason is that, if the amount of the antifoaming agent added is less than 0.1% by weight, the action by which bubbles generated by the reaction between the alkaline aqueous solution and the semiconductor particle 3 can easily escape to the solution level will become small, and hence the crystalline semiconductor particle 3 rises to the solution level of the heated alkaline aqueous solution together with bubbles to be generated when the reaction rapidly progresses so as to generate a region that is not soaked in the alkaline aqueous solution, and therefore the reaction cannot easily progress in the whole of the surface. On the other hand, even if the amount of the antifoaming agent added exceeds 10% by weight, the action by which bubbles generated by the reaction between the alkaline aqueous solution and the semiconductor particle 3 can easily escape to the solution level is not heightened.

The crystalline semiconductor particle 3 whose surface has been roughened in this way is washed with a hydrogen flouride aqueous solution, pure water, or the like.

Thereafter, a layer of a plurality of crystalline semiconductor particles 3 whose surfaces have been roughened in this way are closely arranged on the substrate 1, these are then heated on the whole, and the substrate 1 and the crystalline semiconductor particle 3 are joined together. Thereafter, the semiconductor portion 4 having a roughened surface is formed on the surface of a part of the crystalline semiconductor particle 3 that is not joined to the substrate 1. If the crystalline semiconductor particle 3 is the p-type at this time, the semiconductor portion 4 is formed to be the n type. If the crystalline semiconductor particle 3 is the n-type, the semiconductor portion 4 is formed to be the p-type. It is permitted to form the semiconductor portion 4 by applying a dopant to the crystalline semiconductor particle 3, without forming the semiconductor portion 4 on the crystalline semiconductor particle 3. Alternatively, the substrate 1 and the crystalline semiconductor particle 3 may be joined together after the semiconductor portion 4 is formed by thermally diffusing a dopant to the crystalline semiconductor particle 3. Since the semiconductor portion 4 is formed on the surface of the crystalline semiconductor particle 3 whose surface is a roughened surface, the semiconductor portion 4 can also have a roughened surface formed by following the roughened contours of the crystalline semiconductor particle 3.

Thereafter, the insulator 2 is formed on the substrate 1 in such a way as to fill gaps between the adjoining semiconductor particles that perform a photoelectric conversion. At this time, the quantity of the insulator 2 is adjusted to expose the upper part of the semiconductor portion 4. The photoelectric conversion device of the present invention shown in FIG. 5 can be obtained by further forming the upper electrode 5 in such a way as to cover the upper part of the semiconductor portion 4 and the insulator 2.

As described above, according to the photoelectric conversion device of the present invention of FIG. 5, the joint area of the plurality of crystalline semiconductor particles 3 of one conductivity type whose surfaces have been roughened is joined to the substrate 1 serving a lower electrode, and the semiconductor portion 4 of the opposite conductivity type is formed on the surface excluding the joint area of the crystalline semiconductor particle 3. The insulator 2 is formed between the adjoining crystalline semiconductor particles 3 in such a way as to cover the substrate 1 and the lower part of the semiconductor portion 4 and so as to expose the upper part of the semiconductor portion 4, and the upper electrode 5 is formed in such a way as to cover the insulator 2 and the upper part of the semiconductor portion 4. Therefore, the pn junction area of the semiconductor particle performing a photoelectric conversion can be protected, and the photoelectric conversion device of the present invention can have high conversion efficiency. Additionally, since a grinding step becomes unnecessary, the photoelectric conversion device can have high productivity.

Additionally, since the semiconductor portion 4 is formed also on the surface of the lower half of the crystalline semiconductor particle 3, the area of pn junctions where a photoelectric conversion is performed can be widely taken. Therefore, the photoelectric conversion device can have high conversion efficiency.

Since a high-reflectance material is used for the substrate 1, a large amount of light reflected from the substrate 1 can be guided to the pn junction area of the semiconductor particle performing a photoelectric conversion, and the photoelectric conversion device can have high conversion efficiency.

Since the insulator 2 is made of a high-optical-transmittance material, light can be efficiently guided also to the pn junction area of the lower half of the semiconductor particle performing a photoelectric conversion, and the photoelectric conversion device can have high conversion efficiency.

Since a monocrystalline or twin-crystalline substance is used for the crystalline semiconductor particle 3, the photoelectric conversion device can have high conversion efficiency.

Since the surface of the crystalline semiconductor particle 3 and the surface of the semiconductor portion 4 are roughened, the light capturing effect and the anchor effect are heightened, and the photoelectric conversion device an have high conversion efficiency and high reliability. Additionally, since the light capturing effect and the anchor effect become even high when the surface of the crystalline semiconductor particle 3 is roughened surface having cone-like convex or concave parts, the photoelectric conversion device can have high conversion efficiency and high reliability.

Since “Arithmetic Mean Deviation of the Surface” (Ra) concerning the surface of the crystalline semiconductor particle 3 ranges from 0.1 μm to 30 μm, the anchor effect raises the adhesion between the semiconductor particle performing a photoelectric conversion and the insulator 2, and the photoelectric conversion device can have high reliability. Additionally, since “Arithmetic Mean Deviation of the Surface” (Ra) of the crystalline semiconductor 3 ranges from 0.1 μm to 30 μm, the light capturing effect is heightened, and the photoelectric conversion device can have high conversion efficiency. Additionally, since “Arithmetic Mean Deviation of the Surface” (Ra) of the crystalline semiconductor 3 ranges from 0.1 μm to 30 μm, the thickness of the lower part of the semiconductor portion 4 can be easily reduced on the side of the joint area when the semiconductor portion 4 is formed according to the thin-film producing method. Therefore, a leakage current flowing from the semiconductor portion 4 to the substrate 1 serving as a lower electrode can be restricted, and the photoelectric conversion device can have high conversion efficiency.

Additionally, since the thickness of the zenith part of the semiconductor portion 4 is formed to range from 5 nm to 100 nm, pn junctions can be formed on the crystalline semiconductor particles 3 without gaps, and a leakage current generated while flowing to the substrate 1 serving as a lower electrode through the semiconductor portion 4 can be reduced. Therefore, the photoelectric conversion device can have high conversion efficiency. Additionally, photoabsorption can be reduced by making the semiconductor portion 4 out of a monocrystalline substance or a polycrystalline substance, and light can be efficiently guided to the pn junction area of the semiconductor particle performing a photoelectric conversion. Therefore, the photoelectric conversion device can have high conversion efficiency.

Additionally, since the upper electrode 5 is made of a high optical-transmittance material and is formed to be 300 nm or less in thickness, light can be efficiently guided to the pn junction area of the semiconductor particle performing a photoelectric conversion. Therefore, the photoelectric conversion device can have high conversion efficiency. Additionally, since resistance is lowered by setting the thickness of the upper electrode 5 at 50 nm or more, the photoelectric conversion device can have high conversion efficiency.

According to the manufacturing method of the photoelectric conversion device of the present invention, the crystalline semiconductor particle 3 is joined to the substrate 1 after the surface of the crystalline semiconductor particle 3 is roughened. Therefore, in comparison with a case in which the surface of the crystalline semiconductor particle 3 is roughened after the substrate 1 and the crystalline semiconductor particle 3 are joined together, the surface can be roughened without generating a defect in the joint area between the substrate 1 and the crystalline semiconductor particle 3 and in the substrate 1, and, since the crystalline semiconductor particle 3 can be satisfactorily washed after the completion of the surface-roughening step, there never occurs a deterioration in the quality of pn junctions caused by contamination such as smudges or residue of an etchant resulting from the surface-roughening step. Therefore, a photoelectric conversion device having high conversion efficiency can be manufactured. Additionally, since the surface of the crystalline semiconductor particle 3 is roughened, the crystalline semiconductor particle 3 can be placed on the substrate 1 without rolling, and the crystalline semiconductor particle 3 can be easily fixed when the substrate 1 and the crystalline semiconductor particle 3 are joined together. Therefore, the photoelectric conversion device of the present invention can be easily produced. Additionally, the surface is roughened in a mixed solution obtained by mixing an antifoaming agent ranging from 0.1% by weight to 10% by weight and a alkaline aqueous solution ranging from 0.5% by weight to 15% by weight together and by heating these to a temperature ranging from 60° C. to 90° C. Therefore, cone-like convex or concave parts can be formed over the whole of the crystalline semiconductor particle 3 without needing a large-scale apparatus. Additionally, since non-uniform, con-like convex or concave parts are formed by subjecting the crystalline semiconductor particle 3 to a thermal alkaline process, the light capturing effect and the anchor effect are heightened, and the photoelectric conversion device can have high conversion efficiency and high reliability.

Without being limited to the above-mentioned embodiment, the photoelectric conversion device of the present invention can be produced by applying various changes and improvements in a range not departing from the gist of the present invention.

For example, the crystalline semiconductor particle 3 may be elliptic or columnar although this is spherical in the above-mentioned embodiment. Additionally, without being limited to the single-junction type photoelectric conversion device, the present invention can be applied to a plural-junction type photoelectric conversion device, in which the same effect can be expected. For example, as such a plural-junction type photoelectric conversion device, a tandem type photoelectric conversion device may be used in which an n-type microcrystalline semiconductor layer is formed on the p-type crystalline semiconductor particle 3, and the a p type amorphous semiconductor layer, and i-type amorphous semiconductor layer, and an n type amorphous semiconductor layer are sequentially formed thereon with an interlayer therebetween.

### EXAMPLE 1

Referring to the photoelectric conversion device of FIG. 1, and example in which the present invention is embodied will be described.

First, a crystalline semiconductor particle 3 made of a p-type silicon that is a granular crystal having a mean particle diameter of 700 μm was heated for 40 minutes at 850° C. in a mixed gas of phosphorous oxychloride, oxygen, and nitrogen, and then the phosphorus is thermally diffused, whereby an n-type semiconductor portion 4 having a thickness of 500 nm was formed on the outer hull of the crystalline semiconductor particle 3.

Thereafter, a layer of the crystalline semiconductor particles 3 were closely arranged on the substrate 1 made of aluminum, and the substrate 1 and the crystalline semiconductor particle 3 were joined together by being heated to 577° C. or more that is the eutectic temperature between aluminum and silicon.

Thereafter, wet etching was carried out while soaking the substrate 1, to which the plurality of semiconductor particles that perform a photoelectric conversion were joined, in a sodium hydroxide aqueous solution of 10% by weight, which was heated to 70° C., for one minute, and a separation portion 6 was formed by removing the matter around the outer periphery on the side of the substrate 1 and the crystalline semiconductor particle 3 and removing the surface part of the substrate 1. At this time, etching conditions were adjusted so that the area of the separation portion 6 can reach ⅕ or less of the surface area of the semiconductor particle that performs a photoelectric conversion.

Thereafter, gaps between the semiconductor particles that perform a photoelectric conversion were filled with an insulator 2 made of epoxy resin so as to expose the upper surface of the semiconductor portion 4, and these were hardened. Thereafter, these were put into a DC sputtering apparatus using a tin-added indium oxide (ITO) target, and an ITO-made upper electrode 5 was formed to have a thickness of 100 nm on the upper part of the semiconductor portion 4 and on the insulator 2.

Thereafter, an auxiliary electrode was formed with a silver paste. As a result of evaluating the electric characteristics, the conversion efficiency was 14.4%.

A photoelectric conversion device in which the separation portion 6 was formed according to a different method was evaluated as a first comparative example. In detail, as in the above-mentioned example, the semiconductor portion 4 was formed on the outer hull of the crystalline semiconductor particle 3, a resist was then applied to the surface of the semiconductor portion 4 excluding the joint area, etching was then carried out with a sodium hydroxide aqueous solution, the semiconductor portion 4 in the joint area was then removed, and a p=type part of the crystalline semiconductor particle 3 was exposed. Thereafter, the substrate 1 and the vicinity of the center part of the joint area of the crystalline semiconductor particle 3 in which the p-type part was exposed were heated to a temperature of 577° C. or more that is the eutectic temperature between aluminum and silicon and were joined together. Thereafter, as in the above-mentioned example, the insulator 2, the upper electrode 5, and the auxiliary electrode were formed. As a result of evaluating the electric characteristics, the conversion efficiency was 9.3%.

Further, a second comparative example was performed. As in the above-mentioned example, the semiconductor portion 4 was formed on the outer hull of the crystalline semiconductor particle 3, and the substrate 1 and the crystalline semiconductor particle 3 were joined together. Thereafter, as in the above-mentioned example, the insulator 2, the upper electrode 5, and the auxiliary electrode were formed without forming the separation portion 6. As a result of evaluating the electric characteristics, the conversion efficiency was 1.8%. The photoelectric conversion device of the example and of the first comparative example in which the separation portion 6 was formed has higher conversion efficiency that the photoelectric conversion device of the second comparative example in which the separation portion 6 was not formed. Presumably, the reason is that a short circuit from the upper electrode 5 to the substrate 1 serving as a lower electrode through the semiconductor portion 4 was effectively prevented by forming the separation portion 6.

Additionally, the photoelectric conversion device of the example has higher conversion efficiency that the photoelectric conversions device of the first comparative example. Presumably, the reason is as follows. When the substrate 1 and the crystalline semiconductor particle 3 are joined together, the photoelectric conversion device of the first comparative example is required to perform alignment so as to be joined in the vicinity of the center part of the joint area of the crystalline semiconductor particle from which the semiconductor portion 4 has been removed. However, this alignment was broken, and, in a certain part, the conversion efficiency was lowered by a short circuit resulting from contact between the substrate 1 and tho semiconductor portion 4. On the other hand, the photoelectric conversion device of the example had higher conversion efficiency, because the separation portion 6 was reliably formed between the substrate 1 and the semiconductor portion 4.

As is understood from the above-mentioned result, the photoelectric conversion device having high conversion efficiency was able to be obtained by separating the substrate and the semiconductor portion 4 from each other by means of the separation portion 6. Additionally, the photoelectric conversion device having high conversion efficiency was able to be easily manufactured with high productivity by removing the vicinity of the outer periphery of the joint area between the substrate 1 and the crystalline semiconductor particle 3 according to the method of forming the separation portion 6 between the substrate 1 and the semiconductor portion 4.

### EXAMPLE 2

Referring to the photoelectric conversion device of FIG. 5, an example in which the present invention is embodied will be described.

First, a crystalline semiconductor particle 3 made of p type silicon that is a spherical crystal having a mean particle diameter of 55 μm was soaked in a mixed solution heated to 75° C. that is composed of KOH of 2% by weight, TPA of 3% by weight, and pure water that is the remainder, and the surface of the crystalline semiconductor particle 3 was roughened by forming cone-like convex or concave parts on the surface thereof. Herein, the seize of the cone-like convex or concave part was formed while changing the time during which it was soaked in the mixed solution and changing the “Arithmetic Mean Deviation of the Surface” (Ra) ranging from less than 0.05 μm to 100 μm as shown in Table 1. The “Arithmetic Mean Deviation of the Surface” (Ra) was calculated by measuring the size of the cone-like convex or concave part with a laser microscope.

Thereafter, a layer of a plurality of the crystalline semiconductor particles 3 whose surfaces have cone-like convex or concave parts were closely arranged on the substrate 1 made of aluminum, and the substrate 1 and the granular crystalline silicon 3 were welded together by being heated to 577° C. or more that is the eutectic temperature between aluminum and silicon.

Thereafter, a semiconductor portion 4 that is an n-type microcrystalline semiconductor layer was formed over the whole of the surface of the crystalline semiconductor particle 3 other that the joint area between the substrate 1 and the crystalline semiconductor particle 3 according to a plasma CVD method so that the thickness at the zenith part reaches 40 nm at a substrate temperature of 250° C. The semiconductor portion 4 was formed so that the thickness of the semiconductor portion 4 is the greatest at the zenith part and gradually becomes smaller proportionately with the approach to the lower part thereof.

Thereafter, gaps between the semiconductor particles that perform a photoelectric conversion were filled with an insulator 2 made of epoxy resin so as to expose the upper part of the semiconductor portion 4, and these were hardened. Thereafter, these were put in to a DC sputtering apparatus using a tin-added indium oxide (ITO) target, and an ITO made upper electrode 5 was formed to have a thickness of 100 nm on the upper part of the semiconductor portion 4 and on the insulator 2.

Table 1 shows results obtained by changing the “Arithmetic Mean Deviation of the Surface” (Ra) concerning the surface of the crystalline semiconductor particle 3 and by evaluating the conversion efficiency according to an electric characteristic evaluation. Table 1 additionally shows results obtained by evaluating initial conversion efficiency and conversion efficiency obtained after a reliability test was made under the condition of being exposed for 2,000 hours in an environment in which the temperature is 80° C., and the relative humidity is 90%.

TABLE 1

| | Arithmetic mean | Initial | Conversion |
|---|---|---|---|
| Sample | deviation of the | conversion | efficiency after |
| No. | surface (Ra) (μm) | efficiency (%) | 2,000 hours (%) |
| 1 | <0.05 | 8.6 | 5.5 |
| 2 | 0.07 | 8.8 | 5.5 |
| 3 | 0.09 | 9.2 | 6.5 |
| 4 | 0.1 | 10.7 | 10.4 |
| 5 | 1 | 11.8 | 11.7 |
| 6 | 5 | 12.0 | 11.8 |
| 7 | 10 | 11.9 | 11.6 |
| 8 | 15 | 11.7 | 11.4 |
| 9 | 20 | 11.7 | 11.3 |
| 10 | 25 | 11.4 | 11.0 |
| 11 | 30 | 11.0 | 10.5 |
| 12 | 31 | 10.0 | 7.7 |
| 13 | 35 | 9.1 | 6.7 |
| 14 | 50 | 7.8 | 4.5 |
| 15 | 100 | 7.4 | 4.2 |

As shown in Table 1, a tendency was displayed in which the conversion efficiency at the beginning has a low degree of 8.6% when the “Arithmetic Mean Deviation of the Surface” (Ra) concerning the surface of the crystalline semiconductor particle 3 is less than 0.05 μm, and the conversion efficiency increases when the “Arithmetic Mean Deviation of the Surface” (Ra) concerning the surface thereof becomes greater to 5 μm, and the conversion efficiency decreases when the “Arithmetic Mean Deviation of the Surface” (Ra) concerning the surface thereof exceeds 5 μm. Presumably, the reason is that the light capturing effect was small when the “Arithmetic Mean Deviation of the Surface” (Ra) concerning the surface of the crystalline semiconductor particle 3 is too small, and, in addition, a leakage current flowing from the upper electrode 5 to the substrate 1 serving as a lower electrode through the semiconductor portion 4 was generated because the semiconductor portion 4 was unable to be thinned on the side of the joint area. On the other hand, presumably, the reason is that, when the “Arithmetic Mean Deviation of the Surface” (Ra) concerning the surface of the crystalline semiconductor particle 4 is too great, the light capturing effect was lowered, and the semiconductor portion 4 was unable to be formed deep into the concave part of the crystalline semiconductor particle 3, and there occurred a covering defective part or a gap between the crystalline semiconductor particle 3 and the semiconductor portion 4.

Additionally, it was understood that, on comparison between the conversion efficiency at the beginning and the conversion efficiency obtained after the reliability test, a great decrease did not occur when the “Arithmetic Mean Deviation of the Surface” (Ra) concerning the surface of the crystalline semiconductor particle 3 ranges from 1 μm to 30 μm, whereas a sharp decrease occurred when the “Arithmetic Mean Deviation of the Surface” (Ra) of the crystalline semiconductor particle is 0.09 μm or less and is 31 μm or more. Presumably, the reason is that the adhesion with respect to the insulator was not improved by the anchor effect when the “Arithmetic Mean Deviation of the Surface” (Ra) of the crystalline semiconductor particle is too small or too great.

As is understood from the results, high reliability and high conversion efficiency were achieved by roughening the surface of the crystalline semiconductor particle 3 while forming cone-like rugged shapes so that the arithmetic surface roughness (Ra) ranges from 0.1 μm to 30 μm.

1. A photoelectric conversion device comprising:
a substrate serving as a lower electrode;
a plurality of crystalline semiconductor particles of one conductivity type, each having a semiconductor portion of an opposite conductivity type on a surface thereof excluding an area joined to the substrate (which is designated as a “joint area”);
an insulator between the crystalline semiconductor particles each of which has been joined to the substrate, the insulator being formed so as to cover a surface of the substrate and a lower part of the crystalline semiconductor particle and so as to expose a part of an upper part of the semiconductor portion; and
an upper electrode formed so as to cover the insulator and the upper part of the semiconductor portion;
wherein the crystalline semiconductor particle is disposed on the substrate in a state in which the substrate and the semiconductor portion of the crystalline semiconductor particle are electrically separated from each other with a separation portion therebetween.

2. The photoelectric conversion device of claim 1, wherein the semiconductor portion is formed on a surface of an upper half of the crystalline semiconductor particle and on a surface of a lower half thereof in the vicinity of the joint area joining to the substrate excluding the joint area.

3. The photoelectric conversion device of claim 1, wherein an area of the separation portion is ⅕ or less than a surface area of the semiconductor particle that performs a photoelectric conversion.

4. The photoelectric conversion device of claim 1, wherein the surface of the crystalline semiconductor particle and the surface of the semiconductor portion are roughened.

5. The photoelectric conversion device of claim 4, wherein an arithmetic mean deviation (Ra) of the surface of the crystalline semiconductor particle ranges from 0.1 μm to 30 μm.

6. The photoelectric conversion device of claim 4, wherein the surface of the crystalline semiconductor particle is a roughened surface having cone-like convex or concave parts.

7. A method for manufacturing a photoelectric conversion device comprising:
a step of joining an area, which is to be joined to a substrate, of a plurality of crystalline semiconductor particles of one conductivity type to the substrate serving as a lower electrode (the area being designated as the “joint area”);
a step of forming a semiconductor portion of an opposite conductivity type on the surface of the crystalline semiconductor particle excluding the joint area;
a step of forming a separation portion by removing material around an outer periphery of the joint area between the substrate and the crystalline semiconductor particle;
a step of forming an insulator between the crystalline semiconductor particles on the substrate so as to cover the surface of the substrate and the lower part of the semiconductor portion and so as to expose the upper part of the semiconductor portion; and
a step of forming an upper electrode covering the insulator and the upper part of the semiconductor portion.

8. The method for manufacturing a photoelectric conversion device according to claim 7, wherein the step of forming a semiconductor portion of an opposite conductivity type of the surface of the crystalline semiconductor particle is to form a semiconductor portion of an opposite conductivity type on the surface of the crystalline semiconductor particle according to a thermal diffusion method.

9. The method for manufacturing a photoelectric conversion device according to claim 7, wherein the step of forming a separation portion is performed by a wet etching process by removing matter around an outer periphery of a joint area between the substrate and the crystalline semiconductor particle.

10. The method for manufacturing a photoelectric conversion device according to claim 7, wherein a step of roughening the surface of the crystalline semiconductor particle is performed prior to the step of joining the plurality of crystalline semiconductor particles of one conductivity type to the substrate serving as a lower electrode.

11. The method for manufacturing a photoelectric conversion device according to claim 10, wherein the step of roughening the surface of the crystalline semiconductor particle is performed by an etching operation using a mixed solution obtained by mixing and heating an alkaline aqueous solution and an antifoaming agent together.
